(19) United States
(12) Patent Application Publication
(10) Pub. No.: US 2007/0232080 A1
(43) Pub. Date: Oct. 4, 2007

(54) Reflow method, pattern generating method, and fabrication method for TFT for LCD

(75) Inventor: Yutaka Asou, Kitkuchi-gun (JP)

Correspondence Address: SMITH, GAMBRELL & RUSSELL, 1850 M STREET, N.W., SUITE 800, WASHINGTON, DC, 20036, US

(73) Assignee: Tokyo Electron Limited

(21) Appl. No.: 11/727,754

(22) Filed: Mar. 28, 2007

(30) Foreign Application Priority Data
Mar. 31, 2006 (JP) JP2006-098973

(51) Int. Cl. H01L 21/31

(52) U.S. Cl. 438/781; 257/E21.026

(57) ABSTRACT

A reflow method includes preparing a to-be-processed object, which includes a first layer, a second layer formed in an upper layer to the first layer, and a resist film, which is directly on the second layer and has a pattern allowing formation of an exposure region in which the first layer is exposed and a coverage region in which the first layer is covered, wherein said resist film has an end thereof protruding out further above the exposure region than the edge of the second layer. The resist film has a shape protruding out further above the exposure region than the edge of the second layer. The method also includes covering a part or all of the exposure region by softening and reflowing the resist film.

### BACKGROUND OF THE INVENTION

1. Field of the Invention

The present invention relates to a resist reflow process in a pattern formation phase for semiconductor devices such as thin-film transistors (TFTs), a pattern formation method using the reflow process, and a method of fabricating a TFT for an LCD using the same.

2. Description of the Related Art

In recent years, semiconductor devices have been further highly integrated and miniaturized. However, the more integration and miniaturization progress, the more complex the semiconductor fabrication process becomes, resulting in higher fabrication cost. Accordingly, consolidating multiple mask-pattern fabrication processes using photolithography is considered, thereby reducing the total number of such processes in order to considerably lower the fabrication cost.

A reflow process allowing omission of some mask-pattern fabrication processes by soaking the resist with an organic solvent to soften the resist and thereby changing the shape of the initial resist pattern is proposed (e.g. see Japanese Patent Application Laid-open No. 2002-334830).

However, the method disclosed in Japanese Patent Application Laid-open No. 2002-334830 has a problem that it is difficult to control the coverage area and the orientation for softening and spreading the initial resist. The fourth embodiment of the above-mentioned Japanese Patent Application Laid-open No. 2002-334830, for example, discloses a technique that reflows a resist mask having differing thicknesses to cover the channel regions of TFTs; wherein as shown in FIG. 1A, for example, while resists 507a and 507b having differing thicknesses are used as masks for the previous etching process, they are formed having the area as an ohmic contact layer 505 and source/drain electrode 506, which are underlying layers, thereupon.

Therefore, as shown in FIG. 1B, the modified reflowed resist 511 after completion of the reflow process goes beyond the area of the ohmic contact layer 505 and the source/drain electrode 506, further extending onto an underlying a−Si layer 504. In other words, since it extends up to peripheral regions Z1 enclosed by dotted lines in FIG. 1B as well as the target region (i.e., channel region 510) for the reflow process, the area (dot area) necessary for fabrication of a single TFT, for example, becomes larger, resulting in difficulty in further improving integrity and miniaturization. Note that reference numeral 503 denotes an insulating film made of a silicon nitride, for example., and reference numeral 510 denotes a channel region, however the gate electrode thereof is omitted for convenience in FIGS. 1A and 1B (the same holds true for FIGS. 2A to 2C).

According to the fifth embodiment in the above-mentioned Japanese Patent Application Laid-open No. 2002-334830, a technique of performing an ashing process using O₂ plasma before resists 507 and 507b having respective differing thicknesses are subjected to a reflow process as shown in FIG. 2A has been proposed as shown in FIG. 2A. As shown in FIG. 2B, the thin region of the resist mask is removed through the O₂ plasma ashing process, reducing the coverage areas of the resists 508a and 508b, which are left adjacent to the channel region 510. Afterwards, the reflow process is performed. However, when the O₂ plasma ashing process is performed, the resist is generally also removed along the width, resulting in formation of steps D between the ends of the underlying layer (source and drain electrodes 506) and the sides of the resists 508a and 508b facing the channel region 510. The steps D cause the softened resist to take a longer time to go over the steps D than flat surfaces, and flow of the resist then stops. Consequently, it is difficult to control the flow orientation.

Even in the case of the flow of the softened resist stopping at the steps D, the flow progresses in a direction, without steps. As a result, an incomplete coverage area by the deformed resist is formed, and at its worst, the deformed resist 511 may not cover the entirety of the channel region 510 as shown in FIG. 2C, and/or may cover a peripheral resist inflow prohibiting region Z₂, bringing about failure in device performance. Furthermore, the stoppage of the softened resist flow at the steps D may cause the reflow process to take longer, decreasing the TFT fabrication throughput.

As described above, according to the technique disclosed in Japanese Patent Application Laid-open No. 2002-334830, if the resist area before the reflow process and the underlying layer are corresponded, flow of the softened resist toward the peripheral regions cannot stop, making it difficult to miniaturize TFTS. On the other hand, if the resist area is reduced relative to that of the underlying layer, steps may develop in a desired spreading direction of the softened resist, stopping the flow (i.e., area extension) of the softened resist at the steps into the target regions, and the functionality thereof as a mask may thus be lost.

### BRIEF SUMMARY OF THE INVENTION

An objective of the present invention is to provide a reflow method capable of controlling flow orientation and flow area of a softened resist.

Another objective of the present invention is to provide a pattern formation method applying such a reflow method.

Yet another objective of the present invention is to provide a fabrication method for a TFT for an LCD applying the reflow method.

According to a first aspect of the present invention, a reflow method includes: preparing a to-be-processed object, which includes a first layer, a second layer formed in an upper layer to the first layer, and a resist film, which is on the second layer and has a pattern allowing formation of an exposure region in which the first layer is exposed and a coverage region in which the first layer is covered, wherein said resist film has an end thereof protruding out further above the exposure region than the edge of the second layer; and covering a part or the entire exposure region by softening and reflowing the resist film.

In the aforementioned reflow method, the resist film has a shape including different regions in thickness of at least a thick region and a thin region relatively thinner than the thick region; and flow orientation of the softened resist may be controlled by the arrangement of the thick region and the thin region, or coverage area of the softened resist may be controlled by the arrangement of the thick region and the thin region.

In the aforementioned reflow method, the resist is deformed in an organic solvent atmosphere.

Furthermore, the thick region and the thin region of the resist film may be formed through half-exposure processing using a half-tone mask and development processing thereafter.

According to a second aspect of the present invention, a pattern formation method, includes: forming a resist film to cover a second layer of a to-be-processed object, which includes a first layer and the second layer formed above the first layer; patterning the resist film; exposing a target region of the first layer by etching the second layer using the patterned resist film as a mask, and forming the end of the resist film in a protrusion shape protruding out further above the target region than the second layer; redeveloping the patterned resist film, and reducing coverage area thereof while maintaining the protrusion shape of the resist film; softening the resist film to be in a reflowed state and deformed, and covering the target region of the first layer by the reflowed resist; etching an exposed region of the first layer using the resist deformed by said reflowing as a mask; removing the resist; and etching a target region of the first layer re-exposed through removal of the resist.

In the above-given pattern formation method, the same method as the reflow method according to the first aspect may be employed when the resist film is subjected to reflowing and when patterning.

Further in the aforementioned pattern formation method, a damaged layer on the resist surface may be removed before redeveloping of the patterned resist film.

Moreover, the to-be-processed object-has a stacked structure in which a gate line and a gate electrode are formed on a substrate, a gate insulating film is formed to cover them, and an a−Si film, a Si film for ohmic contact, and a metallic film for source and drain are then formed on the gate insulating film in order from bottom up, and the to-be-etched film may be the Si film for ohmic contact.

According to a third aspect of the present invention, a fabrication method for a TFT for an LCD includes: forming a gate line and a gate electrode on a substrate; forming a gate insulating film that covers the gate line and the gate electrode; depositing an a−Si film, a Si film for ohmic contact, and a metallic film for source and drain on the gate insulating film in order from the bottom; forming a resist film on the metallic film for source and drain; forming a resist mask for a source electrode and a resist mask for a drain electrode through half-exposure processing and development processing; forming a metallic film for a source electrode and a metallic film for a drain electrode by etching the metallic film for source and drain using the resist mask for a source electrode and the resist mask for a drain electrode as a mask, exposing the underlying Si film for ohmic contact to a concave part for a channel region between the metallic film for a source electrode and the metallic film for a drain electrode, and forming an end of the resist film in a protrusion shape protruding out further to the concave part for a channel region than the end of the metallic film for a source electrode and the metallic film for a drain electrode; redeveloping the patterned resist mask for a source electrode and resist mask for a drain electrode, and reducing respective coverage areas by them with maintaining the protrusion shape; making an organic solvent act on the resist mask for the reduced source electrode and resist mask for the drain electrode to soften them to be in a reflowed state and deformed, and covering by the reflowed resist the Si film for ohmic contact within the concave region for the channel region between the metallic film for the source electrode and the metallic film for the drain electrode; etching the Si film for ohmic contact and the a−Si film in underlayers using the deformed resist resulting from reflowing, the metallic film for a source electrode, and the metallic film for a drain electrode as a mask; removing the resist and re-exposing the Si film for ohmic contact within the concave part for a channel region between the metallic film for a source electrode and the metallic film for a drain electrode; and etching the Si film for ohmic contact exposed to the concave part for a channel region between the metallic film for a source electrode and the metallic film for a drain electrode using the films as a mask.

In the above-given fabrication method for a TFT for an LCD, the same method as the reflow method according to the first aspect may be employed when the resist film is subjected to reflowing.

According to a fourth aspect of the present invention, a storage medium, which is stored with a program for controlling a processing unit to be executed by a computer, is provided. The program is executed by the computer to control the processing unit, so as to implement a reflow method including: preparing a to-be-processed object, which includes a first layer, a second layer formed in an upper layer than the first layer, and a resist film which is formed directly above the second layer and patterned allowing formation of an exposure region in which the first layer is exposed and a coverage region in which the first layer is covered, wherein the resist film has a shape protruding out further above the exposure region than the edge of the second layer; and covering a part or all of the exposure region by softening and reflowing the resist film.

According to the present invention, since the end of the resist film used for reflowing has an overhang shape protruding out further towards the coverage region in which coverage through reflowing than the underlying layer directly below is desired, the softened resist is prevented from stopping at a step, thus reducing reflowing time. Furthermore, controlling the flow orientation of the resist and reflowing the resist into a region in which coverage through reflowing is desired is possible.

### BRIEF DESCRIPTION OF THE DRAWINGS

FIGS. 1A and 1B are cross-sections explaining a conventional reflow method;

FIGS. 2A through 2C are cross-sections explaining the conventional reflow method;

FIG. 3 is a top view of an outline of a reflow processing system;

FIG. 4 is a top view of an outline of a redevelopment/remover unit;

FIG. 5 is a cross-section of a general structure of the redevelopment/remover unit;

FIG. 6 is a cross-section of a general structure of the reflow processing unit (REFLW);

FIGS. 7A through 7C show a principle of the conventional reflow method;

FIGS. 8A through 8C show a principle of a reflow method according to an embodiment of the present invention;

FIGS. 9A through 9C show a principle of a reflow method according to another embodiment of the present invention;

FIG. 10A is a graph explaining a relationship between the flow speed of a softened resist and thinner concentration;

FIG. 10B is a graph explaining a relationship between the flow speed of the softened resist and temperature;

FIG. 10C is a graph explaining a relationship between the flow speed of the softened resist and applied pressure;

FIG. 10D is a graph explaining a relationship between the flow speed of the softened resist and the thinner flow;

FIG. 11 is a flowchart explaining the TFT fabrication process according to an embodiment of the present invention;

FIG. 12 is a vertical cross-section of a substrate in which a gate electrode and a laminated film are formed on an insulating substrate in a TFT fabrication process;

FIG. 13 is a vertical cross-section of a substrate having a resist film formed thereupon in the TFT fabrication process;

FIG. 14 is a vertical cross-section of the substrate being subjected to half-exposure processing in the TFT fabrication process;

FIG. 15 is a vertical cross-section of the substrate after the half-exposure processing is completed in the TFT fabrication process;

FIG. 16 is a vertical cross-section of the substrate after development in the TFT fabrication process;

FIG. 17 is a vertical cross-section of the substrate after a metallic film for electrodes in the TFT fabrication process;

FIG. 18 is a vertical cross-section of the substrate after a preprocess and redevelopment in the TFT fabrication process;

FIG. 19 is a vertical cross-section of the substrate after a reflow process in the TFT fabrication process;

FIG. 20 is a vertical cross-section of the substrate after an n+Si film and an a−Si film are etched in the TFT fabrication process;

FIG. 21 is a vertical cross-section of the substrate after a deformed resist is removed in the TFT fabrication process;

FIG. 22 is a vertical cross-section of the substrate having a channel region formed therein in the TFT fabrication process;

FIG. 23 is a top view of the substrate shown in FIG. 18; and

FIG. 24 is a top view of the substrate shown in FIG. 19.

### DESCRIPTION OF THE PREFERRED EMBODIMENTS

Preferred embodiments according to the present invention are described forthwith while referencing the drawings.

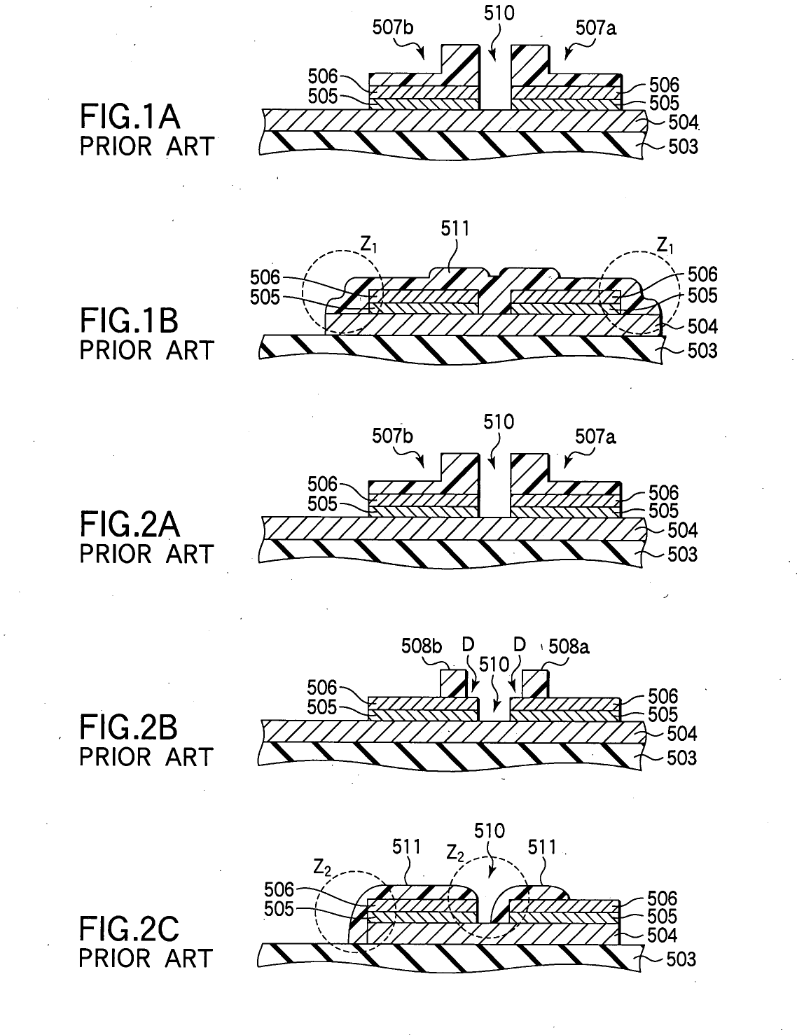

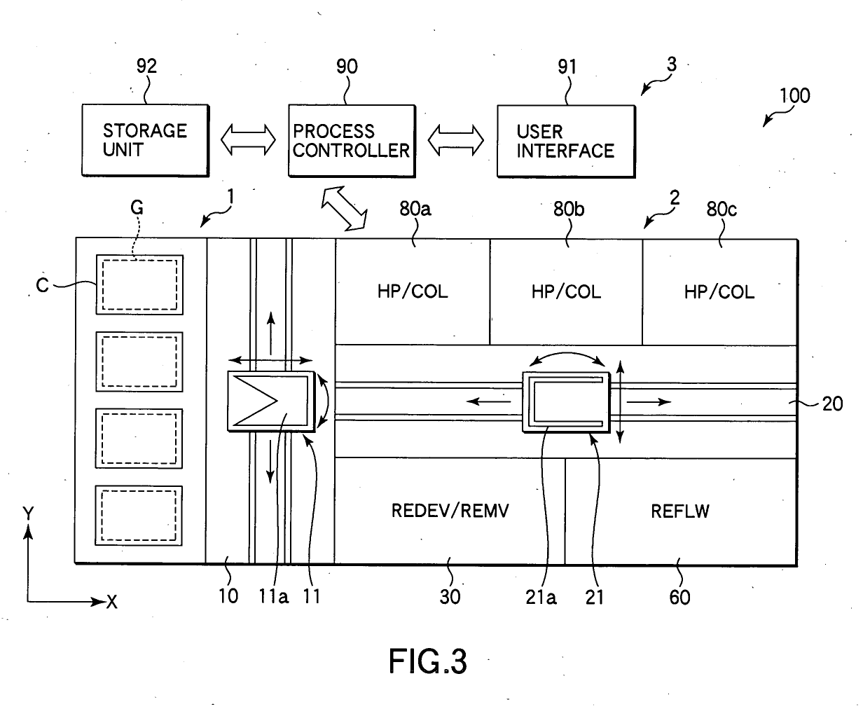

FIG. 3 is a top view of an entire reflow processing system available according to a reflow method of the present invention. Here, a reflow processing system including a reflow processing unit, which softens and deforms a resist film formed on an LCD glass substrate (hereafter simply called ‘substrate’) after development and then performs reflowing to re-cover, and a redevelopment/remover unit (REDEV/REMV), which performs redevelopment and preprocessing before reflowing, is described as an example. This reflow processing system 100 includes a cassette station (carry-in/out unit) 1 in which each cassette C accommodating multiple substrates G is placed, a processing station (processing unit) 2, which includes multiple processing units for performing successive processing such as reflow processing and redevelopment processing for each substrate G, and a control unit 3, which controls each unit of the reflow processing system 100. Note that the direction along the length of the reflow processing system 100 is defined as X direction while direction perpendicular to the X direction on a plane is defined as Y direction in FIG. 1.

The cassette station 1 is deployed next to an end of the processing station 2. The cassette station 1 including a transfer unit 11, which carries in and out the substrates G between the cassette C and the processing station 2, and carries in and out the cassettes C from/to the outside. The transfer unit 11 has a transfer arm 11 a movable along a transfer path 10 extending in the Y direction in which the cassettes C are aligned. This transfer arm 11a is provided capable of moving back and forth in the X direction, moving up and down, and rotating, allowing transfer of the substrates G between the cassette C and the processing station 2.

The processing station 2 includes multiple processing units, which perform successive processes for resist reflowing, preprocessing, and redevelopment processing for the substrates G. Each of these processing units processes the substrates G one by one. The processing station 2 also includes a central transfer path 20 for transferring the substrates G basically extending in the X direction. The processing units are deployed at both ends of this central transfer path 20, facing the central transfer path 20.

A transfer unit 21, which carries in and out the substrates G between each processing unit, is provided along the central transfer path 20 and has a transfer arm 21 a movable in the X direction in which the processing units are deployed. This transfer arm 21a is provided capable of moving back and forth in the Y direction, moving up and down, and rotating, allowing transfer of the substrates G between each processing unit.

On one side along the central transfer path 20 of the processing station 2, a redevelopment/remover unit (REDEV/REMV) 30 and a reflow processing unit (REFLW) 60 are aligned in this order from the cassette station 1 side while at the other side along the central transfer path 20 of the processing station 2, three heating/cooling units (HP/COLs) 80a, 80b, and 80c are deployed in a line. Each of the heating/cooling units (HP/COLs) 80a, 80b, and 80c is made up of multiple layers stacked vertically (omitted from the drawing).

The redevelopment/remover unit (REDEV/REMV) 30 is a processing unit, which performs preprocessing for removal of a damaged layer in a metal etching process or other related processes by another processing system not shown in the drawing and redevelopment processing for redevelopment of a resist pattern previous to reflowing. This redevelopment/remover unit (REDEV/REMV) 30 includes a fluid spinning/processing unit, which has a redevelopment chemical discharge nozzle for redevelopment and a removal fluid discharge nozzle for preprocessing to discharge a treatment fluid onto a substrate G while holding and rotating the substrate G at a fixed speed to allow application of the processing liquid for redevelopment and preprocessing (i.e., removing the damaged layer on the resist surface).

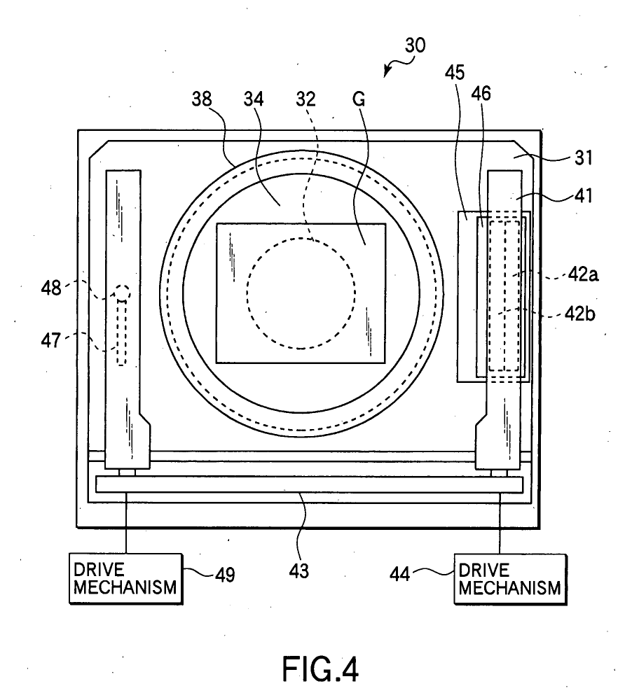

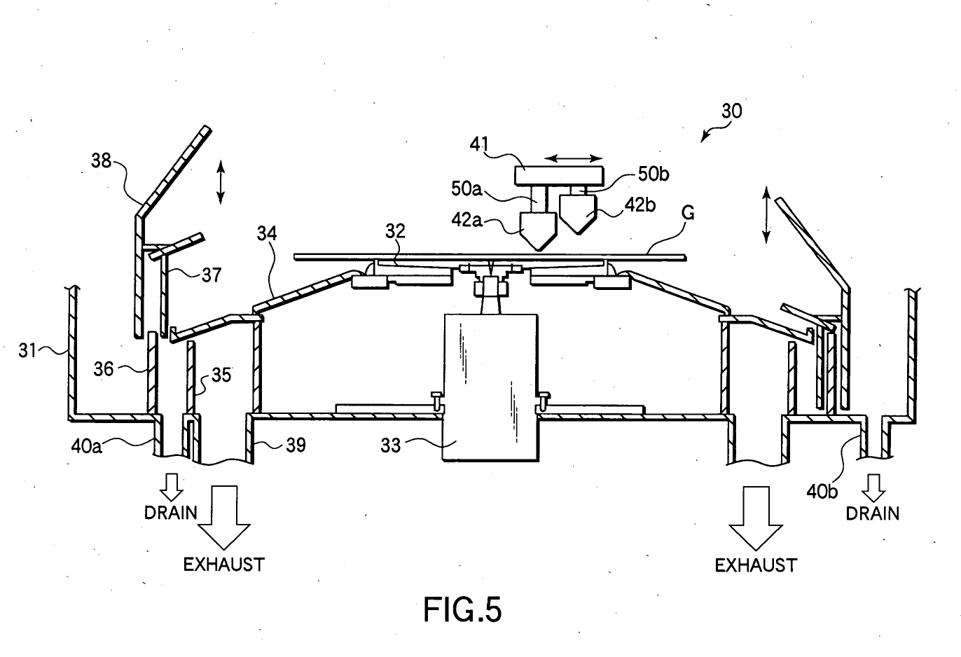

Now, the redevelopment/remover unit (REDEV/REMV) 30 is described while referencing FIGS. 4 and 5. FIG. 4 is a top view of the redevelopment/remover unit (REDEV/REMV) 30 while FIG. 5 is a cross-section of a cup of the redevelopment/remover unit (REDEV/REMV) 30. As shown in FIG. 2, the entirety of the redevelopment/remover unit (REDEV/REMV) 30 is enclosed by a sink 31. As shown in FIG. 3, the redevelopment/remover unit (REDEV/REMV) 30 has a holding means such as a spin chuck 32, which holds a substrate G mechanically and is rotated by a rotation driving mechanism 33 such as a motor. A cover 34 enclosing the rotation driving mechanism 33, is deployed under this spin chuck 32. The spin chuck 32 is capable of moving up and down under the control of a lifting mechanism not shown in the drawing, transferring the substrate G from/to the transfer arm 21a at a lifting position. This spin chuck 32 is capable of adsorptive retention of the substrate G using vacuum attracting force, or other forces.

Two undercups 35 and 36 are deployed on the periphery of a cover 34 at a distance from each other. Above the two undercups 35 and 36, an innercup 37, which mainly passes a redevelopment chemical downwards, is provided to freely move up and down. At the outside of the undercup 36, an outercup 38, which mainly passes a rinsing fluid downwards, is integrally provided capable of moving up and down in conjunction with the innercup 37. Note that rising positions of the innercup 37 and the outercup 38 when the redevelopment chemical is being discharged are shown on the left side of FIG. 5, and lowering positions thereof when the rinsing fluid is being discharged are shown on the right side.

An exhaust outlet 39 is provided on the inner bottom of the undercup 35 to evacuate the unit when spinning and drying. A drain pipe 40a is deployed between the two undercups 35 and 36 to mainly drain redevelopment chemical, and a drain pipe 40b is deployed on the outer bottom of the undercup 36 to mainly drain rinsing fluid.

As shown in FIG. 4, on one side of the outercup 38, a nozzle holding arm 41 for supplying the redevelopment chemical and removal fluid is deployed, wherein the nozzle holding arm 41 accommodates a redevelopment chemical discharge nozzle 42a for applying the redevelopment chemical to substrate G and a removal fluid discharge nozzle 42b.

A nozzle holding arm 41 is structured movable along the length of a guide rail 43 across the substrate G under the control of a drive mechanism 44 for driving a belt and the like. For application of the redevelopment chemical and discharge of the removal fluid, the nozzle holding arm 41 scans a stationary substrate G while the redevelopment chemical discharge nozzle 42a is discharging the redevelopment chemical or the removal fluid discharge nozzle 42b is discharging the removal fluid.

The redevelopment chemical discharge nozzle 42a and the removal fluid discharge nozzle 42b can be retracted in a nozzle retraction region 45, which accommodates a nozzle cleaning mechanism 46 for cleaning the redevelopment chemical discharge nozzle 42a and the removal fluid discharge nozzle 42b.

On the other side of the outercup 38, a nozzle holding arm 47 for discharging a rinsing fluid such as pure water is deployed while a rinsing fluid discharge nozzle 48 is, deployed at the edge of the nozzle holding arm 47. The rinsing fluid discharge nozzle 48 may have a pipe-shaped discharge opening, for example. The nozzle holding arm 47 is structured capable of sliding along the length of a guide rail 43 under the control of a drive mechanism 49 and scanning the substrate G while the rinsing fluid discharge nozzle 48 is discharging the rinsing fluid.

Next, an outline of preprocessing and redevelopment processing using the aforementioned redevelopment/remover unit (REDEV/REMV) 30 is described. First, the innercup 37 and the outercup 38 are positioned at a lower position (i.e., the position shown on the right side of FIG. 5), the transfer arm 21a holding a substrate G is inserted to the redevelopment/remover unit (REDEV/REMV) 30, the spin chuck 32 is lifted at the same timing, and the substrate G is then transferred into the spin chuck 32. Once the transfer arm 21a is retracted from the redevelopment/remover unit (REDEV/REMV) 30, the spin chuck 32 on which the substrate G is mounted is lowered and then kept at a predetermined position. Then, the nozzle holding arm 41 moves to and stays at the predetermined position in the innercup 37, a lifting mechanism 50b is extended to move and hold only the removal fluid discharge nozzle 42b at a lower position, and an alkaline removal fluid is discharged onto the substrate G using the removal fluid discharge nozzle 42b while the substrate G is scanned. A strong alkaline aqueous solution, for example, may be used as the removal fluid. During a predetermined reaction time, the lifting mechanism 50b contracts to return the removal fluid discharge nozzle 42b to an upper position and stay there, the nozzle holding arm 41 is retracted from the innercup 37 and the outercup 38, the nozzle holding arm 47 is then driven instead to move the rinsing fluid discharge nozzle 48 up to a predetermined position on the substrate G. Afterwards, the innercup 37 and the outercup 38 are lifted and then kept at the upper position (on the left side of FIG. 5).

The substrate G is then rotated at a low speed, and as the removal fluid on the substrate G is about to be shaken off, the rinsing fluid discharge nozzle 48 starts discharging the rinsing fluid. At almost the same time as this operation starts, an exhaust outlet 39 starts evacuating. The removal fluid and the rinsing fluid scattering towards the outer area of the substrate G after the substrate G starts rotating hit the tapered part of the innercup 37 and/or external wall (vertical side wall) and are then guided down to drain from the drain pipe 40a.

After a predetermined time has elapsed since the substrate G as started rotating, the innercup 37 and the outercup 38 are lowered and then kept at a lower position while discharging the rinsing fluid and also rotating the substrate G. At the lower position, the horizontal position of the substrate G is set to be almost the same as that of the tapered part of the outercup 38. In order to decrease the amount of residual removal fluid, the rotation speed of the substrate G is set to be greater than the initial rotation speed that allows the removal fluid to be shaken off. The operation of increasing the rotation speed of this substrate G may be performed any time such as at the same time as, after, or before the innercup 37 and the outercup 38 are lowered. In this manner, treatment fluid mainly made of rinsing fluid scattering from the substrate G hits the tapered part of the outercup 38 and/or the external wall and is then drained from the drain pipe 40b. Next, discharging the rinsing fluid is stopped, the rinsing fluid discharge nozzle 48 is stored at a predetermined position, and the rotation speed of the substrate G is further increased and then kept for a predetermined duration. In other words, spin drying for drying the substrate G is performed by rotating it at a high speed.

Then, the nozzle holding arm 41 moves to and stays at the predetermined position in the innercup 37, a lifting mechanism 50a is extended to move and hold only the redevelopment chemical discharge nozzle 42a at a lower position, and a predetermined redevelopment chemical is applied to the substrate G using the redevelopment chemical discharge nozzle 42a while the substrate G is scanned, forming a redevelopment chemical puddle. During a predetermined redevelopment processing time (redevelopment reaction time) after the redevelopment chemical puddle is formed, the lifting mechanism 50a returns the redevelopment chemical discharge nozzle 42a to an upper position and holds it there, the nozzle holding arm 41 is retracted from the innercup 37 and the outercup 38, the nozzle holding arm 47 is then driven instead to move the redevelopment chemical discharge nozzle 48 up to a predetermined position on the substrate G. Afterwards, the innercup 37 and the outercup 38 are lifted and then kept at the upper position (on the left side of FIG. 5).

The substrate G is then rotated at a low speed, and as the redevelopment chemical on the substrate G is about to be shaken off, the rinsing fluid discharge nozzle 48 starts discharging the rinsing fluid. At almost the same time as this operation starts, an exhaust outlet 39 starts evacuating. In other words, before the redevelopment reaction time elapses, it is preferable for the exhaust outlet 39 not to function, and thus no adverse influence such as air current development due to the operation of the exhaust outlet 39 develops on the redevelopment chemical puddle formed on the substrate G.

The redevelopment chemical and the rinsing fluid scattering towards the outer area of the substrate G after the substrate G starts rotating hit the tapered part of the innercup 37 and/or external wall (vertical side wall) and are then guided down to drain from the drain pipe 40a.

After a predetermined time has elapsed since the substrate G as started rotating, the innercup 37 and the outercup 38 are lowered and then kept at a lower position while discharging the rinsing fluid and also rotating the substrate G. At the lower position, the horizontal position of the substrate G is set to be almost the same as that of the tapered part of the outercup 38. In order to decrease the amount of residual redevelopment chemical, the rotation speed of the substrate G is set to be greater than the initial rotation speed that allows the redevelopment chemical to be shaken off. The operation of increasing the rotation speed of this substrate G may be performed any time such as at the same time as, after, or before the innercup 37 and the outercup 38 are lowered. In this manner, treatment fluid mainly made of rinsing fluid scattering from the substrate G hits the tapered part of the outercup 38 and/or the external wall and is then drained from the drain pipe 40b. Next, discharging the rinsing fluid is stopped, the rinsing fluid discharge nozzle 48 is stored at a predetermined position, and the rotation speed of the substrate G is further increased and then kept for a predetermined duration. In other words, spin drying for drying the substrate G is performed by rotating it at a high speed.

In this manner described above, successive processing by the redevelopment/remover unit (REDEV/REMV) 30 is completed. Afterwards, in the reverse order to that described above, the transfer arm 21a carries the processed substrate G out from the redevelopment/remover unit (REDEV/REMV) 30.

On the other hand, the reflow processing unit (REFLW) 60 of the processing station 2 performs reflowing by softening a resist formed on the substrate G using an organic solvent such as a thinner atmosphere and thereby re-covering.

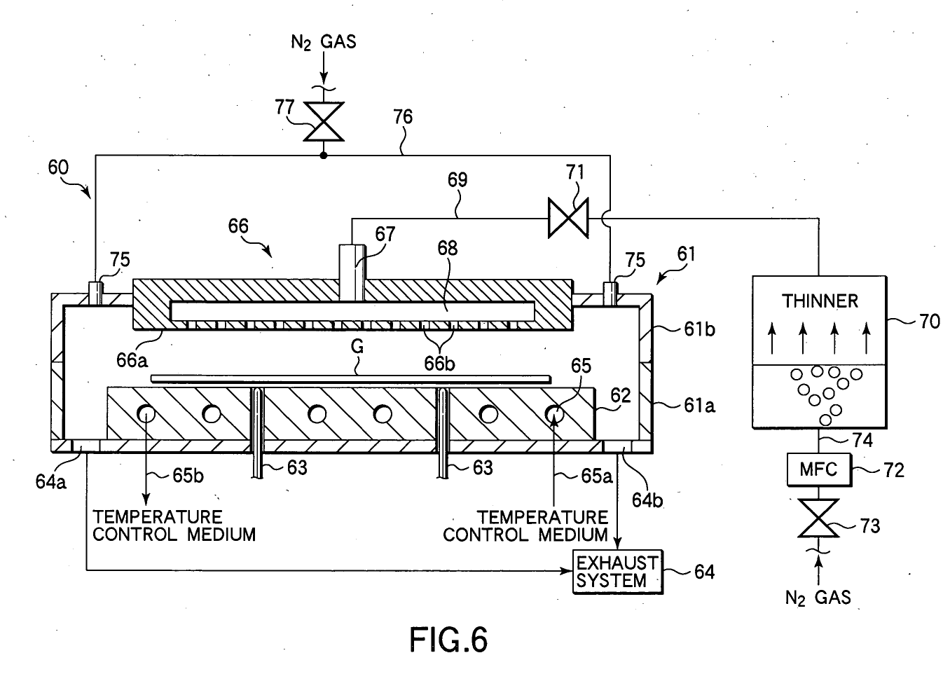

Now, the structure of the reflow processing unit (REFLW) 60 is described in detail. FIG. 6 is a cross-section of an outline of the reflow processing unit (REFLW) 60. The reflow processing unit (REFLW) 60 includes a chamber 61. The chamber 61 includes a lower chamber 61a and an upper chamber 61b connected to the upper part of the lower chamber 61a. The upper chamber 61b and the lower chamber 61a are structured to be able to open and close by an open/close mechanism not shown in the drawing; wherein the transfer unit 21 carries in/out the substrate G when it is closed.

Within this chamber 61, a supporting table 62 horizontally supporting the substrate G is provided. The supporting table 62 is made of a material such as aluminum superior in thermal conductivity.

The supporting table 62 includes three lifting pins 63 (only two are illustrated in FIG. 6), which are driven by a lifting mechanism to raise and lower the substrate G and pass through the supporting table 62. These lifting pins 63 lift the substrate G from the supporting table 62 up to a predetermined position when the substrate G is transferred between the lifting pins 63 and the transfer unit 21, and they are held so that the tips thereof are in height the same as the upper surface of the supporting table 62 while the substrate G is being subjected to reflowing.

Exhaust outlets 64a and 64b connected to a exhaust system 64 are formed at the bottom of the lower chamber 61a. The ambient gas in the chamber 61 is evacuated through this exhaust system 64.

A temperature adjustment medium flow path 65 is provided in the supporting table 62. A temperature adjustment medium such as temperature control coolant is introduced to this temperature adjustment medium flow path 65 via a temperature adjustment medium introduction pipe 65a and then drained from the temperature adjustment medium drain pipe 65b and circulated. The heat (e.g., for cooling) is transferred via the supporting table 62 to the substrate G, thereby controlling the temperature of the to-be-processed surface of the substrate G to be a predetermined temperature.

A shower head 66 is provided on the ceiling of the chamber 61, facing the supporting table 62. Numerous gas discharge holes 66b are formed in the undersurface 66a of this shower head 66.

A gas lead-in part 67 is provided at the upper center of the shower head 66 and coupled to a space 68 formed inside of the shower head 66. A gas supplying pipe 69 is connected to the gas lead-in part 67, and a bubbler tank 70, which supplies an organic solvent such as thinner vapor, is connected to the other end of the gas supplying pipe 69. Note that an on-off valve 71 is provided on the gas supplying pipe 69.

A N₂ gas supplying pipe 74 connected to a N₂ gas supplying source not shown in the drawing is provided as a bubble generation means to vaporize thinner at the bottom of the bubbler tank 70. A mass flow controller 72 and an on-off valve 73 are provided on the N₂ gas supplying pipe 74. The bubbler tank 70 includes a temperature adjustment mechanism not shown in the drawing, which adjusts the temperature of the thinner stored inside to a predetermined temperature. It is structured to allow introduction of N₂ gas from the N₂ gas supplying source not shown in the drawing to the bottom of the bubbler tank 70 under the control of the mass flow controller 72 that controls the flow thereof, vaporization of the thinner in the bubbler tank 70 in which the temperature is adjusted to a predetermined temperature, and introduction of the resulting gas to the chamber 61 via the gas supplying pipe 69.

Multiple purge gas lead-in parts 75 are provided at the upper rim of the shower head 66, and a purge gas supplying pipe 76, which supplies a purge gas such as N₂ gas to the chamber 61, is connected to each purge gas lead-in part 75. The purge gas supplying pipe 76 is connected to a purge gas supplying source not shown in the drawing, and an on-off valve 77 is provided therebetween.

First, in such a structure of the reflow processing unit (REFLW) 60, the upper chamber 61b is disconnected from the lower chamber 61a. In this state, the transfer arm 21a of the transfer unit 21 carries in a substrate G having a resist pattern provided through preprocessing and redevelopment, and then mounts it on the supporting table 62. The upper chamber 61b is connected to the lower chamber 61a, and the chamber 61 is then closed. Afterwards, the on-off valve 71 of the gas supplying pipe 69 and the on-off valve 73 of the N₂ gas supplying pipe 74 are opened. The N₂ gas flow is adjusted by the mass flow controller 72 and a vaporized amount of thinner is controlled. The bubbler tank 70 sends the resultant thinner vapor to the space 68 of the shower head 66 via the gas supplying pipe 69 and the gas lead-in part 67, and the vapor is then output from the gas discharge holes 66b. Consequently, the chamber 61 confines a predetermined density of thinner atmosphere.

Since a resist pattern is formed on the substrate G mounted on the supporting table 62 in the chamber 61, this resist is exposed to the thinner atmosphere, resulting in penetration of the thinner into the resist. As a result, the resist softens and its fluidity increases, and the resist deforms, covering a predetermined area (target region) of the surface of the substrate G. At this time, the temperature adjustment medium is introduced to the temperature adjustment medium flow path 65 provided in the supporting table 62, heat thereof transfers to the substrate G via the supporting table 62, and the temperature of the to-be-processed surface of the substrate G is adjusted to a predetermined temperature such as 20C degrees. Once the gas including thinner discharged onto the surface of the substrate G from the shower head 66 hits the surface of the substrate G, it flows towards the exhaust outlets 64a and 64b and is consequently discharged out from the chamber 61.

As described above, after the reflow processing unit (REFLW) 60 has completed reflowing, the on-off valve 77 on the purge gas supplying pipe 76 is opened while continuing to discharge, and N₂ gas as a purge gas is introduced to the chamber 61 via the purge gas lead-in part 75, replacing the inner-chamber atmosphere. Afterwards, the upper chamber 61b is disconnected from the lower chamber 61a. In reverse order to that described above, the transfer arm 21a carries out the substrate G subjected to reflowing from the reflow processing unit (REFLW) 60.

Each of the three heating/cooling units (HP/COL) 80a, 80b, and 80c includes a hot plate unit (HP) for heating each substrate G and a cooling plate unit (COL) for cooling down each substrate G, which are stacked (not shown in the drawing) These heating/cooling units (HP/COL) 80a, 80b, and 80c heat and cool down the substrate G subjected to preprocessing, redevelopment processing, and reflowing as necessary.

As shown in FIG. 3, each unit of the reflow processing system 100 is connected to process controller 90, which includes a CPU in the control unit 3. The process controller 90 has a user interface 91 connected thereto, which includes a keyboard used by a process manager to enter commands for managing the reflow processing system 100 and a display or the like for displaying a visualized operating status of the reflow processing system 100.

The process controller 90 also has a storage unit 92 connected thereto, which is stored with recipes including control programs to be executed for a variety of processes by the process controller 90 in the reflow processing unit 100 and process condition data, etc.

In conformity with a command or the like from the user interface 91, a recipe is then retrieved from the storage unit 92 as necessary and executed by the process controller 90; in other words, a desired process is performed by the ref low processing unit 100 under the control of the process controller 90. The recipes described above may be stored in computer-readable storage media such as CD-ROM, hard disk, flexible disk, or flash memory, or they may be transmitted from other apparatus via a dedicated communication line, for example.

In the reflow processing unit 100 structured as described above, first, the transfer arm la of the transfer unit 11 in the cassette station 1 accesses a cassette C accommodating unprocessed substrates G and retrieves a single substrates. The substrate G is transferred from the transfer arm 11a of the transfer unit 11 down to the transfer arm 21a of the transfer unit 21 running along the central transfer path 20 in the processing station 2; this transfer unit 21 carries it into the redevelopment/remover unit (REDEV/REMV) 30. Afterwards, once the redevelopment/remover unit (REDEV/REMV) 30 has performed preprocessing and redevelopment processing, the substrate G is retrieved from the redevelopment/remover unit (REDEV/REMV) 30 by the transfer unit 21, and then carried to one of the heating/cooling units (HP/COL) 80a, 80b, and 80c. The substrate G subjected to the predetermined heating and cooling in each of the heating/cooling units (HP/COL) 80a, 80b, and 80c is carried to the reflow processing unit (REFLW) 60, which then performs reflowing. After the reflowing is completed, predetermined heating and cooling is performed by each of the heating/cooling units (HP/COL) 80a, 80b, and 80c as necessary. The substrate G gone through such successive processing is transferred down to the transfer unit 11 of the cassette station 1 by the transfer unit 21.

Next, a principle of the reflow method used in the reflow processing unit (REFLW) 60 is described.

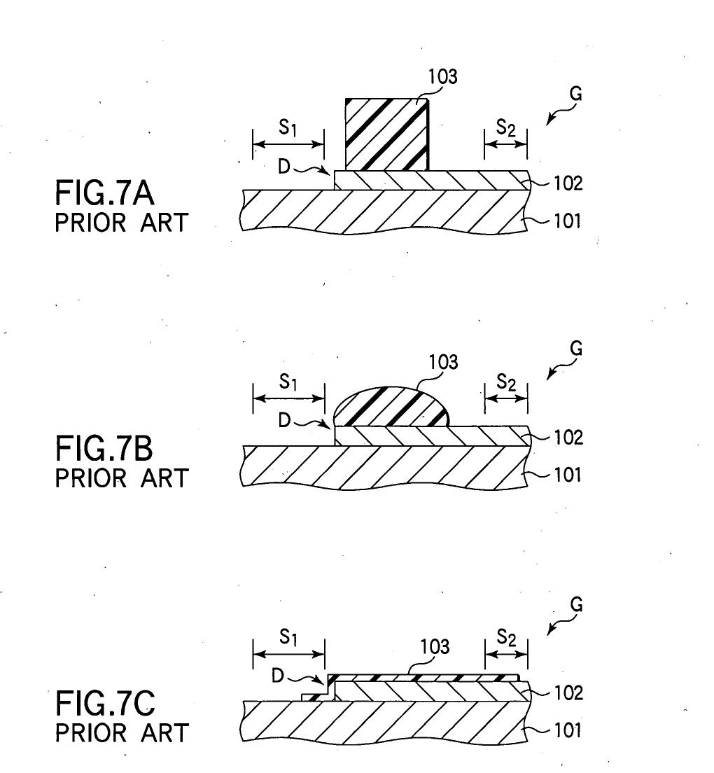

FIG. 7A shows a simplified cross-section of a resist 103 formed around the surface of a substrate G, explaining a conventional reflow method. The shape of the resist 103 surface is flat herein. An underlying layer 101 and an underlying layer 102 are stacked on the substrate G. Further on the resulting surface, the patterned resist 103 is formed.

According to the example of FIG. 7A, target region S₁ exists on the surface of the underlying layer 101. Softened resist 103 flows to this target region S₁ and covers it. On the other hand, prohibiting region S₂ such as an etching region exists on the surface of the underlying layer 102, wherein this underlying layer 102 must avoid being covered by the resist 103. The end of the underlying layer 102 protrudes laterally towards the target region S₁ rather than the side of the resist 103, and a step D is formed therebetween. Such a step D is formed by redeveloping the resist 103 and thereby shaving the resist 103 laterally.

In the state shown in FIG. 7A, an organic solvent such as thinner is made to touch and penetrate into the resist to soften and deform the resist 103 as shown in FIG. 7B. Since the softened resist 103 increases in fluidity, it spreads across the surface of the underlying layer 102. However, since it cannot go over the step D until the thickness of the flowing resist 103 exceeds a fixed height, the moving speed of the resist 103 gets slower at the step D where the resist 103 stops moving ahead.

Due to such stoppage at around this step D, the resist 103 moves in the opposite direction to the step D where it is easy to flow. In other words, most of it tends to move towards a prohibiting region S₂ where coverage with the resist should be avoided. As shown in FIG. 7C, the resist 103 does not cover the target region S₁ sufficiently, but reaches the prohibiting region S₂ and covers the surface thereof. When coverage of the target region S₁ is not complete such that the resist 103 reaches the prohibiting region S₂ where coverage with the resist is not desired, precision of the etched shape formed using, for example, the reflowed resist 103 decreases, resulting in failures in devices such as TFTs and decrease in yield. The state of the resist 103 described with reference to FIGS. 7A through 7C emanates from not being able to control the flow direction of the resist 103 softened by the organic solvent.

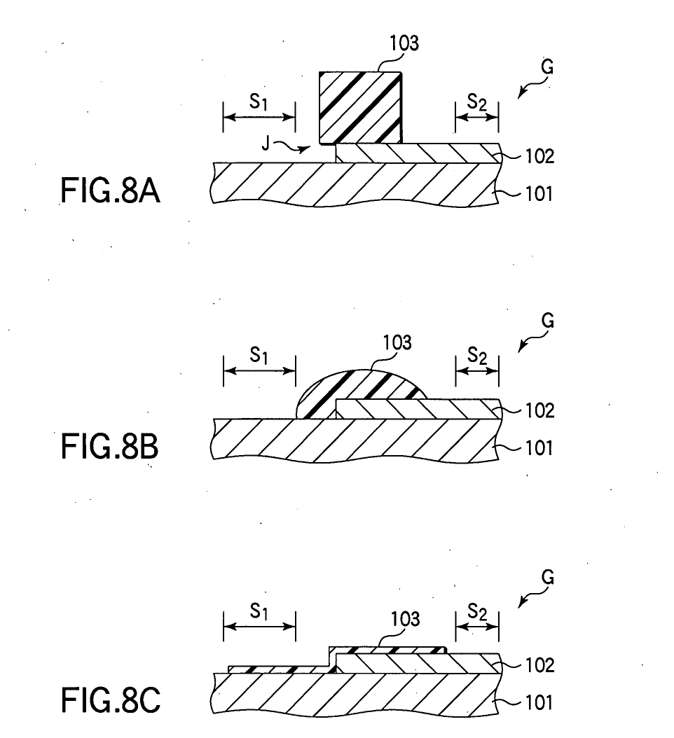

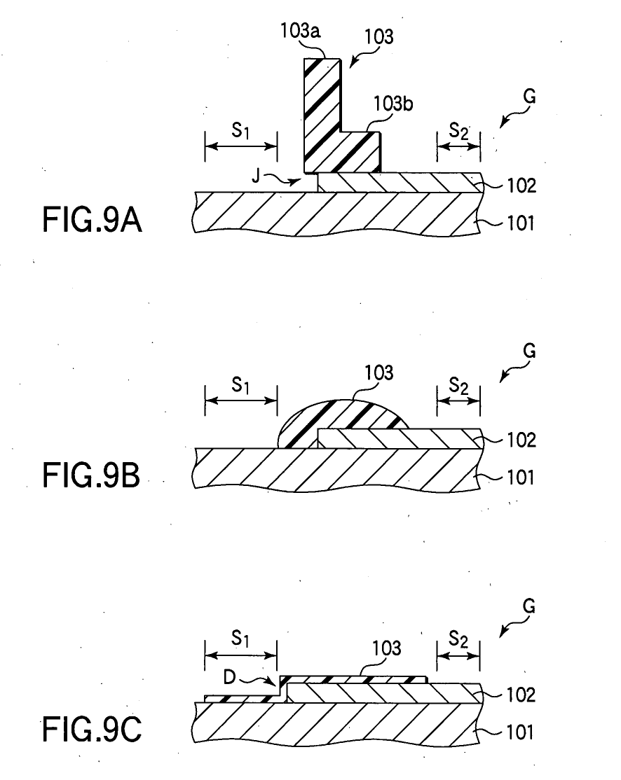

FIGS. 8A through 8C and 9A through 9C describe an idea of the reflow method according to the present invention.

FIG. 8A shows a simplified cross-section of the resist 103 formed around the surface of the substrate G. The target region S₁, the prohibiting region S₂, and the structure where an underlying layer 101 and an underlying layer 102 are stacked and formed and thereupon the patterned resist 103 is then formed are the same as those shown in FIG. 7A. However, in this embodiment, a lower end J of the resist 103 facing the target region S₁ is formed in an overhang shape, protruding further towards the target region S₁ than the end of the underlying layer 102.

In the state shown in FIG. 8A, an organic solvent such as thinner is made to touch the resist to soften and deform the resist 103. The softened resist 103 increases influidity, spreading across the surface of the underlying layer 102. As mentioned above, since the lower end J of the resist 103 is formed protruding further towards the target region Si than the end of the underlying layer 102, flow of the resist towards the target region S₁ progresses smoothly unimpeded by the underlying layer 102. This becomes even clearer through comparison of FIGS. 7A and 7B.

In other words, as shown in FIG. 7A, when a step D exists during progression of the softened resist 103, the softened resist 103 stops there (see FIG. 7B), thereby requiring a fixed time period until it goes over the step D. Furthermore, since the softened resist 103 flows in a direction that allows easier flow while stopping at the step D, control of the flow orientation becomes difficult. On the contrary, as shown in FIG. 8A, by making the lower end J of the resist 103 protrude out further than the underlying layer 102 in advance, the resist 103 does not stop (see FIG. 8B), and the softened resist may be made to flow swiftly to the target region S₁. Furthermore, an overhang shape is provided on the target region S₁ side where it is desired for the resist 103 to flow, the flow of the resist 103 to the prohibiting region S₂ is controlled as a reaction to promoting the flow of the resist 103, and as shown in FIG. 8C, deformation is stopped without reaching the prohibiting region S₂. This allows secure etching precision using the reflowed resist 103 as a mask, and favorable device characteristics.

In this manner, by making the lower end J of the resist 103 protrude out further than the underlying layer 102 in advance, the resist 103 may spread faster, shortening the reflowing time and controlling the flow orientation, thus providing secure and sufficient etching precision.

FIG. 9A shows a simplified cross-section of the resist 103 formed around the surface of the substrate G. The target region S₁, the prohibiting region S₂, and the structure where an underlying layer 101 and an underlying layer 102 are stacked and formed, thereupon the patterned resist 103 is then formed, and the lower end J of the resist 103 facing the target region S₁ is formed in an overhang shape, protruding further towards the target region S₁ than the end of the underlying layer 102 are the same as those shown in FIG. 8A.

The resist 103 according to the present invention has parts differing in thickness, and a step on the surface. In other words, there are different regions in height on the surface of the resist 103, having a thick region 103a and a thin region 103b thinner than this thick region 103a. The thick region 103a is formed on the target region S₁ side while the thin region 103b is formed on the prohibiting region S₂ side.

In the state shown in FIG. 9A, an organic solvent such as thinner is made to touch the resist to soften and deform the resist 103. The softened resist 103 increases in fluidity, spreading towards the target region S₁, as shown in FIG. 9B. As mentioned above, since the resist 103 includes the lower end J overhanging towards the target region S₁, and the thick region 103a and the thin region 103b also exist, the flow speed of the softened resist 103 further quickens, and control of the flow orientation is assured.

In other words, since the lower end J of the resist 103 protrudes out further than the underlying layer 102, the resist 103 does not stop, and thus the softened resist may be made to flow to the target region S1 swiftly. Furthermore, since the thick region 103a has a large exposed area to the thinner atmosphere, the thinner penetrates easily, resulting in a faster softening speed and high fluidity. Furthermore, since the thick region 103a has a relatively fast softening speed and has a large resist volume, it is easier for the resist 103 to reach the target region S₁.

On the other hand, the thin region 103b has a smaller exposed area to the thinner atmosphere than the thick region 103a, thus softening speed thereof is not fast and fluidity does not increase as much as the thick region 103a. Furthermore, the thin region 103b has a slower softening speed and a smaller resist volume than the thick region 103a, and thus flow of the resist 103 towards the prohibiting region S₂ is controlled, and as shown in FIG. 7C, deformation stops without reaching the prohibiting region S₂. This allows secure etching precision using the reflowed resist 103 as a mask, and favorable device characteristics.

In this manner, use of the resist 103 having different regions in height on the surface including the thick region 103a and the thin region 103b, and formation of the lower end J of the resist 103 in an overhang shape allows a shortened spreading time for the resist 103, control of the flow orientation thereof, and secure and sufficient etching precision.

Note that in the embodiment according to FIGS. 9A through 9C, while in the resist 103 provided with a different regions in height on the surface including the thick region 103a and the thin region 103b thinner than this thick region 103a, the thick region 103a is formed on the target region S₁ side and the thin region 103b is formed on the prohibiting region S₂ side, forming the thin region 103b on the prohibiting region S₁ side and the thick region 103a on the target region S₂ side is also possible. The reason why such arrangements are possible is because the flow state of the resist 103 changes in conformity with conditions such as thinner concentration, flow rate, temperature of the substrate G (supporting table 62), and inner pressure of the chamber 61 when the reflow processing unit (REFLW) 60 performs reflowing.

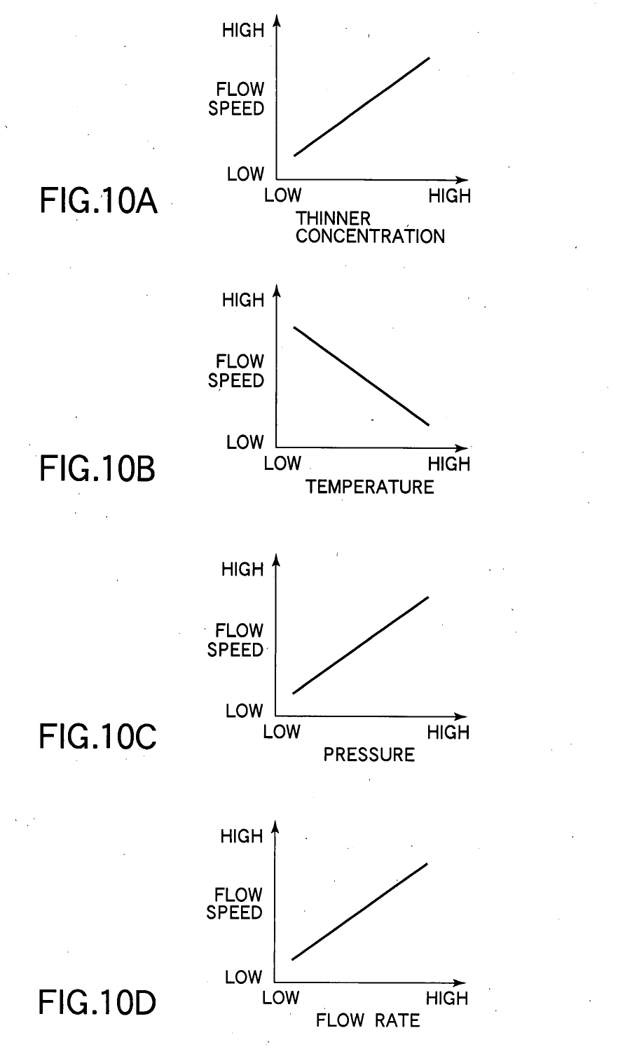

As shown in FIGS. 10A through 10D, for example, while thinner concentration, flow rate, and chamber inner pressure increase and flow speed of the resist also increases, flow speed of the resist 103 tends to decrease as the temperature increases. In other words, even if the form and location of the thick region 103a and the thin region 103b were the same, the degree of softening of the resist would change due to the thinner concentration within the chamber 61, for example, and behaviors such as flow orientation and flow speed would be different. Accordingly, use of the resist 103 having different regions in height (the thick region and the thin region) on the surface allows control of its flow orientation and coverage area as needed under determined and selected experimental optimum conditions such as combined conditions of organic solvent concentration, flow rate, substrate temperature and pressure during reflowing.

Note that while the resist film is structured including thick films and thin films in the embodiment according to FIGS. 7A through 7C, change in resist thickness is not limited to two levels and may have three or more levels. Moreover, not only can the resist thickness be varied to be a staircase shape, but it may be formed to have a slanted surface such that the thickness gradually varies. In this case, a slanted surface may be formed on the resist surface after half-exposure by giving a slant to the applied film thickness of the resist in advance.

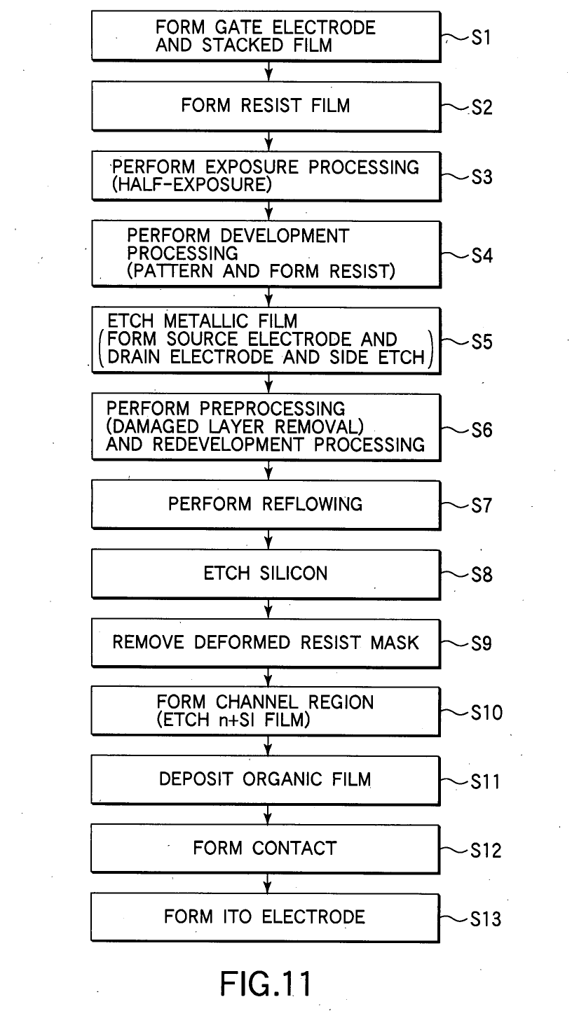

Next, an embodiment of a fabrication process for a TFT for an LCD using the reflow method according to the present invention is described while referencing FIGS. 11 through 24. FIG. 11 is a flowchart showing an outline of the fabrication method for a TFT for an LCD according to the embodiment of the present invention.

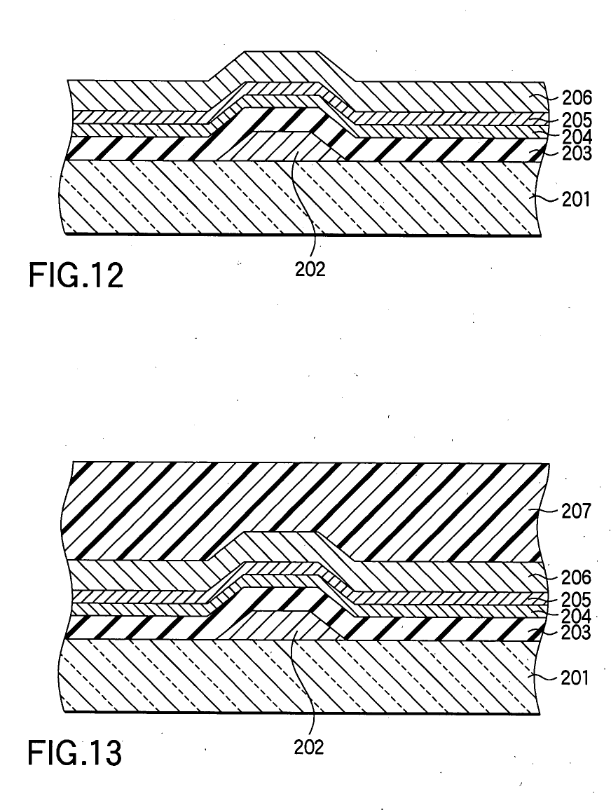

First, as shown in FIG. 12, a gate electrode 201 and a gate line not shown in the drawing are formed on an insulating substrate 202 made of a transparent substrate such as glass, and a gate insulating film 203 such as a silicon nitride film, an amorphous silicon (a−Si) film 204, an n+Si film 205 to be used as an ohmic layer, and a metallic film 206 for electrodes are stacked and deposited in this order (Step S1).

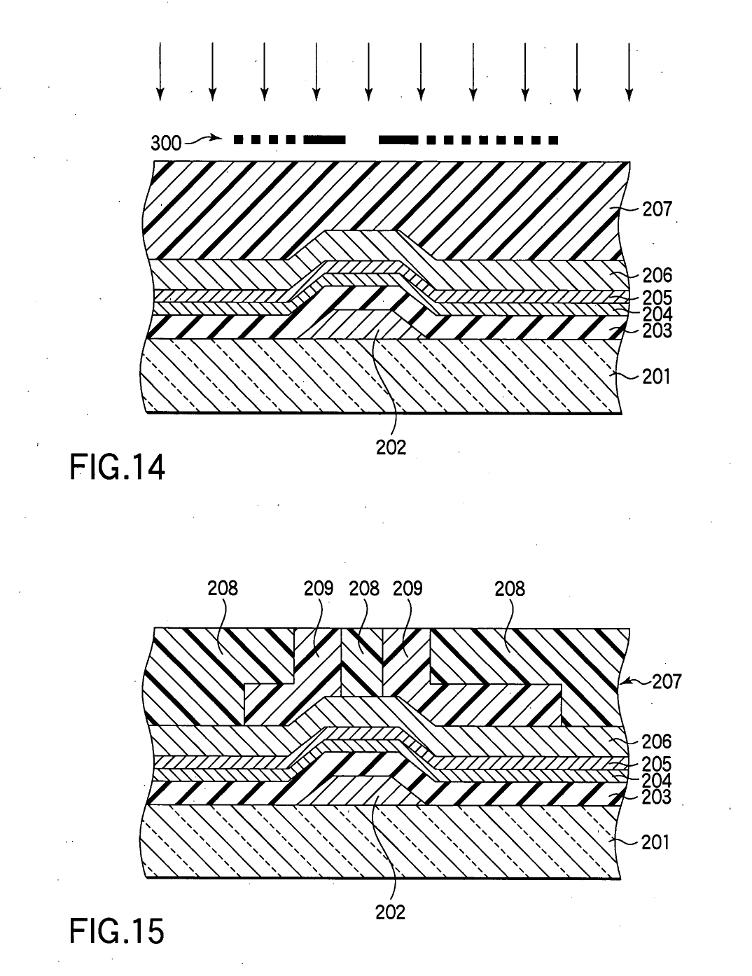

Next, as shown in FIG. 13, a resist 207 is formed on the metallic film 206 for electrodes (Step S2). As shown in FIG. 14, exposure processing is then performed using a half-tone mask 300 as an exposure mask, which have different regions in transmissivity of light and is capable of varying light exposure for respective regions of the resist 207 (Step S3). This half-tone mask 300 may be structured to provide two different exposures for the resist 207. Performing half-exposure on the resist 207 in this manner results in formation of exposed resist regions 208 and unexposed resist regions 209, as shown in FIG. 15. The unexposed resist regions 209 are formed into a staircase shape at the borders with the exposed resist regions 208 due to the transmissivity of the mask 300.

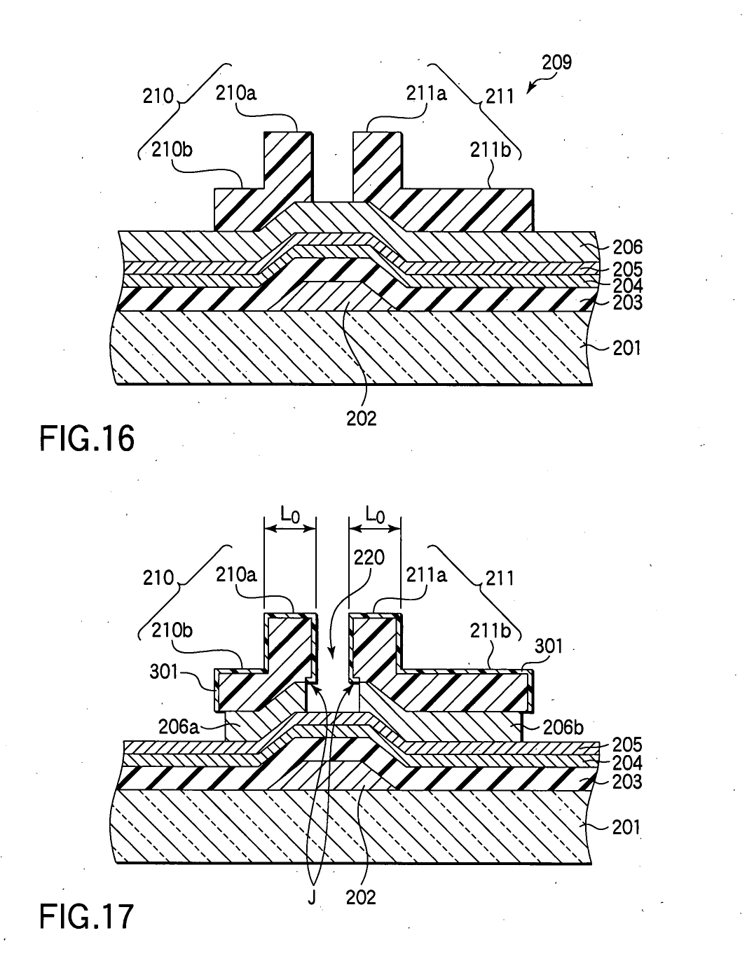

Development is performed after exposure, thereby removing the exposed resist regions 208, leaving the unexposed resist regions 209 on the metallic film 206 for electrodes, as shown in FIG. 16 (Step S4). The unexposed resist regions 209 are separated into a resist mask 210 for source electrodes and a resist mask 211 for drain electrodes, configuring a pattern. The resist mask 210 for source electrodes includes a first thick region 210a and a second thick region 210b in order of thickness formed in a staircase shape through half-exposure. The resist, mask 211 for drain electrodes includes a first thick region 211a and a second thick region 211b in order of thickness formed in a staircase shape through half-exposure.

Afterwards, the metallic film 206 for electrodes is etched using the remaining unexposed resist regions 209 as an etching mask, and as shown in FIG. 17, a concave portion. 220, which will become a channel region later, is formed (Step S5). As a result of this etching, a source electrode 206a and a drain electrode 206b may be formed to expose the surface of the n+Si film 205 within the concave portion 220 between the electrodes. This etching may be dry etching using an etching gas plasma, or it may be wet etching using an etchant. At this time, the source electrode 206a and the drain electrode 206b are side etched a predetermined amount crosswise, forming undercuts, and lower edges J of the respective resist mask 210 for source electrodes and resist mask 211 for drain electrodes, which are an etching mask, are etched such that they become an overhang shape protruding out further towards the concave part 220 than the source electrode 206a and the drain electrode 206b. With dry etching, for example, by selecting an etching gas that allows generation of an isotropic etchant and then over etching, side etching progresses, and an etched undercut shape as shown in FIG. 15 is possible. This kind of side etching of the source electrode 206a and the drain electrode 206b uses a chlorinated gas such as Cl₂, BCl₃, and CCl₄ as an etching gas type when dry etching, and may be implemented under a pressure of approximately 10 to 100 Pa, for example.

Furthermore, thin surface damaged layers 301 are formed through etching near the surfaces of the resist mask 210 for source electrodes and the resist mask 211 for drain electrodes.

Next, wet processing is performed using a removal fluid, the surface damaged layers 301 are removed (preprocessing), and redevelopment processing is then performed for partially removing the unexposed resist regions 209 on the source electrode 206a and the drain electrode 206b (Step S6). This preprocessing and redevelopment processing may be continuously performed by the redevelopment/remover unit (REDEV/REMV) 30 of the reflow processing system 100.

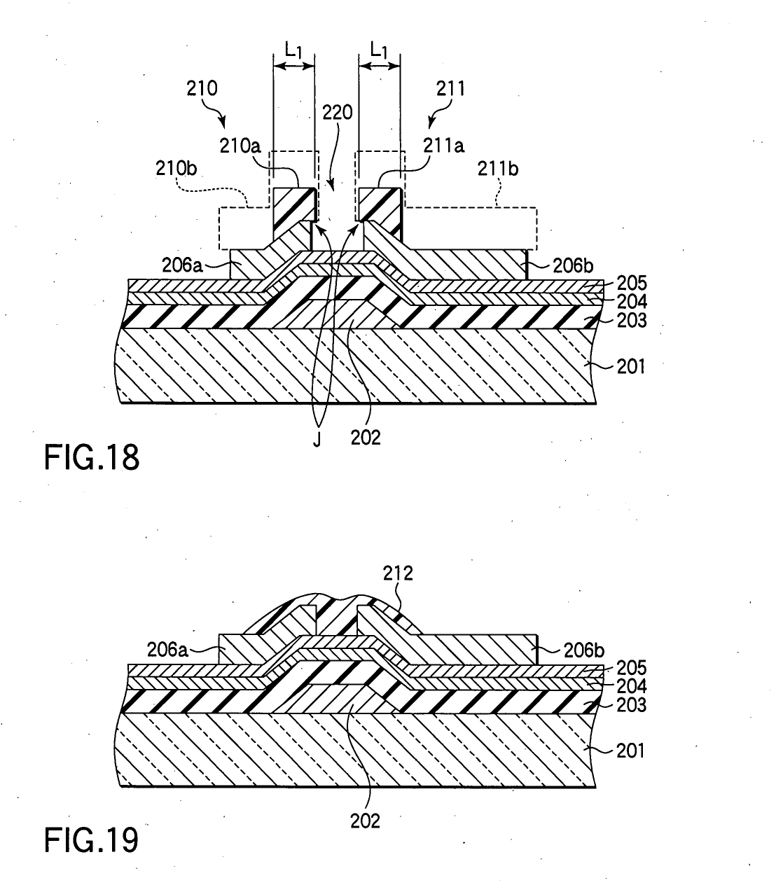

Through this redevelopment processing, the coverage areas by the resist mask 210 for source electrodes and the resist mask 211 for drain electrodes are considerably reduced, as shown in FIG. 18. More specifically, of the resist mask 210 for source electrodes, the second thick region 210b is completely removed, and only the first thick region 210a is left on the source electrode 206a. Furthermore, even of the resist mask 211 for drain electrodes, the second thick region 211b is completely removed, and only the first thick region 211a is left on the drain electrode 206b. Furthermore, thickness of the first thick region 210a (or the first thick region 211a) and lateral thickness (width) L₁ become smaller than lateral thickness (width) L₀ before redevelopment through redevelopment processing. However, even if the coverage area by the resist mask 210 for source electrodes and the resist mask 211 for drain electrodes is reduced, the respective lower ends J maintain an overhang shape that protrudes out further towards the concave part 220 than the end of the source electrode 206a and the end of the drain electrode 206b. Therefore, out of consideration for amount of resist to be shaved through the preprocessing/redevelopment processing of step S6 ahead of time, amount of side etching (amount that the lower ends J protrude) the source electrode 206a and the end of the drain electrode 206b in the etching of the metallic film of step S5 is adjusted.

In this manner, the coverage areas by the resist mask 210 for source electrodes and the resist mask 211 for drain electrodes are reduced through redevelopment processing, thereby preventing the deformed reflowed resist from protruding out from the end of the source electrode 206a or the end of the drain electrode 206b that are on opposite sides of a target region (concave portion 220) and covering underlayers. As a result, miniaturization of TFTs is possible.

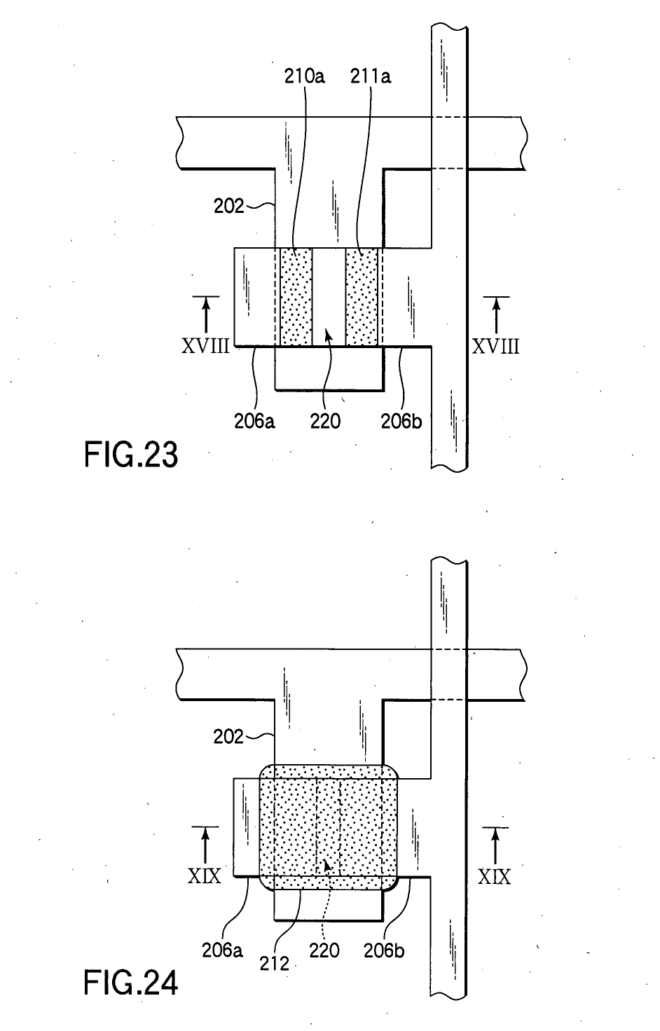

Note that in FIG. 18, contours of the resist mask 210 for source electrodes and the resist mask 211 for drain electrodes before redevelopment processing are indicated by dotted lines for comparison. Furthermore, the top view corresponding to the cross section shown in FIG. 18 is shown in FIG. 23.

With this embodiment, by making the lower edges J of the respective resist mask 210 for source electrodes and resist mask 211 for drain electrodes protrude out further than the ends of the source electrode 206a and the drain electrode 206b so as for the softened resist to easily flow into the concave part 220 of the target region, the flow orientation of the softened resist is controlled and the processing time is shortened. In the reflowing (Step S7), the resist softened by an organic solvent such as thinner is then made to flow into the concave part 220, which is intended to become a channel region later, in a short time, and thus the concave part 220 may be securely covered. This reflowing is performed by the reflow processing unit (REFLW) 60 of FIG. 6.

FIG. 19 shows that the periphery of the concave part 220 is covered by a deformed resist 212. Furthermore, the top view corresponding to the cross-section shown in FIG. 19 is shown in FIG. 24.

With the conventional technology, there is a problem that since the deformed resist 212 spreads up to the other side of the concave part 220 of the source electrode 206a and the drain electrode 206b and covers the n+Si film 205, which is an ohmic contact layer, for example, the covered parts are not etched in the following silicon etching process, and etching precision is lost, thereby bringing about TFT failure and reduction in yield. Furthermore, there is a problem that if the coverage area by the deformed resist 212 is largely estimated beforehand and then designed, necessary area (dot area) for fabricating a single TFT increases, and high integration and miniaturization of TFTs is difficult.

On the contrary, with this embodiment, since reflowing is performed after drastically reducing the volume of the resist mask 210 for source electrodes and the resist mask 211 for drain electrodes through redevelopment processing, the covered region by the deformed resist 212 is limited to the periphery of the concave part 220, which is the target region for reflowing, and the thickness of the deformed resist 212 is formed thin. This allows high integration and miniaturization of TFTs.

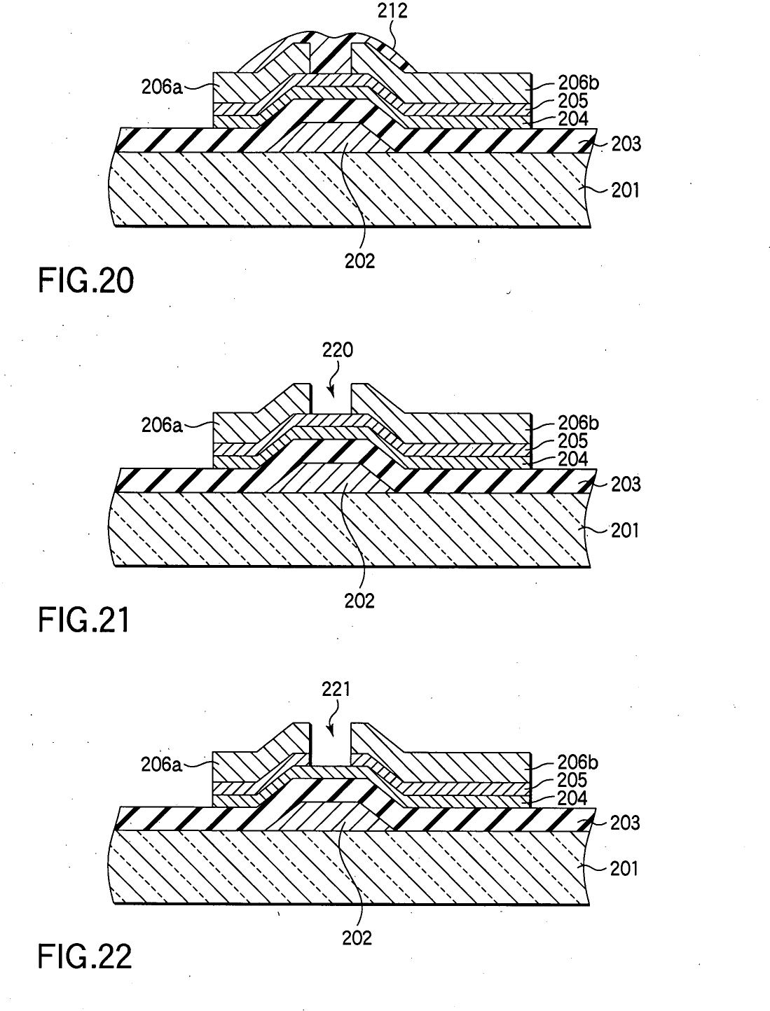

Next, as shown in FIG. 20, the n+Si film 205 and the a−Si film 204 are etched using the source electrode 206a, the drain electrode 206b and the deformed resist 212 as an etching mask (Step S8). Afterwards, as shown in FIG. 21, the deformed resist 212 is removed through wet processing or other related processing, for example (Step S9). The n+Si film 205 exposed in the concave part 220 is then etched using the source electrode 206a and the drain electrode 206b as an etching mask (Step S10). As a result, a channel region 221 is formed, as shown in FIG. 22.

While subsequent processes have been omitted from the drawings, an organic film is formed so as to cover the channel region 221, the source electrode 206a, and the drain electrode 206b (Step S11), a contact hole connected to the source electrode 206a (drain electrode 206b) is formed through photolithography and etching (Step S12), and a transparent electrode made of indium-tin oxide (ITO) or the like is then formed (Step S13). As a result, a TFT for an LCD is fabricated.

As is comprehensible from the description of this embodiment given above, according to the present invention, use of a resist film having an overhang shape allows prevention of the softened resist from stopping at a step and thus reduction of reflowing time, and controlling the flow orientation of the resist and flow of the softened resist into a region desired to be covered through reflowing is secured. Therefore, use of the reflow method according to the present invention for fabrication of semiconductor devices such as TFT fabricated by conducting an etching process repeatedly using a resist as a mask allows omission of masks and reduction in number of processes. Accordingly, it is possible to achieve reduction in processing time and improvement in etching precision, and contribute to high integration and miniaturization of semiconductor devices.

Note that the present invention is not limited to the above-given embodiment, and various modifications are possible within the scope of the present invention. For example, the example of TFT fabrication using a glass substrate for an LCD is given in the above-given description; however, the present invention may also be applied to reflowing for a resist formed on a substrate such as a another flat panel display (FPD) substrate or a semiconductor substrate.

What is claimed is:

1. A reflow method comprising:
preparing a to-be-processed object, which includes a first layer, a second layer formed in an upper layer to the first layer, and a resist film, which is directly on the second layer and has a pattern allowing formation of an exposure region in which the first layer is exposed and a coverage region in which the first layer is covered, wherein said resist film has an end thereof protruding out further above the exposure region than the edge of the second layer; and
covering a part or the entire exposure region by softening and reflowing the resist film.

2. The reflow method according to claim 1, wherein the resist film has a shape including different regions in thickness of at least a thick region and a thin region relatively thinner than the thick region; and
flow orientation of the softened resist is controlled by the arrangement of the thick region and the thin region.

3. The reflow method according to claim 1, wherein the resist film has a shape including different regions in thickness of at least a thick region and a thin region relatively thinner than the thick region; and
coverage area of the softened resist is controlled by the arrangement of the thick region and the thin region.

4. The reflow method according to claim 1, wherein the resist is deformed in an organic solvent atmosphere.

5. The reflow method according to claim 1, wherein the thick region and the thin region of the resist film are formed through half-exposure processing using a half-tone mask and development processing thereafter.

6. A pattern formation method, comprising:
forming a resist film to cover a second layer of a to-be-processed object, which includes a first layer and the second layer formed above the first layer;
patterning the resist film;
exposing a target region of the first layer by etching the second layer using the patterned resist film as a mask, and forming the end of the resist film in a protrusion shape protruding out further above the target region than the second layer;
redeveloping the patterned resist film, and reducing coverage area thereof while maintaining the protrusion shape of the resist film;
softening the resist film to be in a reflowed state and deformed, and covering the target region of the first layer by the reflowed resist;
etching an exposed region of the first layer using the resist deformed by said reflowing as a mask;
removing the resist; and
etching a target region of the first layer re-exposed through removal of the resist.

7. The pattern formation method according to claim 6, wherein the resist film has a shape including different regions in thickness of at least a thick region and a thin region relatively thinner than the thick region; and
controlling flow orientation of the softened resist by the arrangement of the thick region and the thin region when the resist film is subjected to reflowing.

8. The pattern formation method according to claim 6, wherein the resist film has a shape including different regions in thickness of at least a thick region and a thin region relatively thinner than the thick region; and
coverage area by the softened resist is controlled by the arrangement of the thick region and the thin region when the resist is subjected to reflowing.

9. The pattern formation method according to claim 6, wherein the resist is deformed in an organic solvent atmosphere when the resist film is subjected to reflowing.

10. The pattern formation method according to claim 6, further comprising removing a damaged layer on the resist surface before redeveloping of the patterned resist film.

11. The pattern formation method according to claim 6, wherein the thick region and the thin region of the resist film are formed through half-exposure processing using a half-tone mask and development processing thereafter in patterning of the resist film.

12. The pattern formation method according to claim 6, wherein a to-be-processed object has a stacked structure in which a gate line and a gate electrode are formed on a substrate, a gate insulating film is formed to cover them, and an a−Si film, a Si film for ohmic contact, and a metallic film for source and drain are then formed on the gate insulating film in order from bottom up; and
the first layer is the Si film for ohmic contact, and the second layer is a metallic film for source and drain.

13. A fabrication method for a TFT for an LCD, comprising:
forming a gate line and a gate electrode on a substrate;
forming a gate insulating film that covers the gate line and the gate electrode;
depositing an a−Si film, a Si film for ohmic contact, and a metallic film for source and drain on the gate insulating film in order from the bottom;
forming a resist film on the metallic film for source and drain;
forming a resist mask for a source electrode and a resist mask for a drain electrode through half-exposure processing and development processing;
forming a metallic film for a source electrode and a metallic film for a drain electrode by etching the metallic film for source and drain using the resist mask for a source electrode and the resist mask for a drain electrode as a mask, exposing the underlying Si film for ohmic contact to a concave part for a channel region between the metallic film for a source electrode and the metallic film for a drain electrode, and forming an end of the resist film in a protrusion shape protruding out further to the concave part for a channel region than the end of the metallic film for a source electrode, and the metallic film for a drain electrode;
redeveloping the patterned resist mask for a source electrode and resist mask for a drain electrode, and reducing respective coverage areas by them while maintaining the protrusion shape;
making an organic solvent act on the resist mask for the reduced source electrode and resist mask for the drain electrode to soften them to be in a reflowed state and deformed, and covering by the reflowed resist the Si film for ohmic contact within the concave region for the channel region between the metallic film for the source electrode and the metallic film for the drain electrode;
etching the Si film for ohmic contact and the a−Si film in underlayers using the deformed resist resulting from reflowing, the metallic film for a source electrode, and the metallic film for a drain electrode as a mask;
removing the resist and re-exposing the Si film for ohmic contact within the concave part for a channel region between the metallic film for a source electrode and the metallic film for a drain electrode; and
etching the Si film for ohmic contact exposed to the concave part for a channel region between the metallic film for a source electrode and the metallic film for a drain electrode using the films as a mask.

14. The fabrication method for a TFT according to claim 13, wherein the resist film has a shape comprising different regions in thickness, which include at least a thick region and a thin region relatively thinner than the thick region; and
flow orientation of the softened resist is controlled by the arrangement of the thick region and the thin region when the resist film is subjected to reflowing.

15. The fabrication method for a TFT according to claim 13, wherein the resist film has a shape comprising different regions in thickness, which include at least a thick region and a thin region relatively thinner than the thick region; and
coverage area by the softened resist is controlled by the arrangement of the thick region and the thin region when the resist film is subjected to reflowing.

16. A storage medium, which is stored with a program for controlling a processing unit to be executed by a computer, wherein
said program is executed by the computer to control the processing unit, so as to implement a reflow method including: preparing a to-be-processed object, which includes a first layer, a second layer formed in an upper layer than the first layer, and a resist film which is formed directly above the second layer and patterned allowing formation of an exposure region in which the first layer is exposed and a coverage region in which the first layer is covered, wherein the resist film has a shape protruding out further above the exposure region than the edge of the second layer; and covering a part or all of the exposure region by softening and reflowing the resist film.
